(19) United States
(12) Patent Application Publication
(10) Pub. No.: US 2005/0136693 A1
(43) Pub. Date: Jun. 23, 2005

(54) Thermal processing unit and thermal processing method

(76) Inventors: Kazuhide Hasebe, Tokyo-To (JP); Yutaka Takahashi, Tokyo-To (JP); Kota Umezawa, Tokyo-To (JP); Satoshi Takagi, Tokyo-To (JP); Mitsuhiro Okada, Tokyo-To (JP); Takashi Chiba, Tokyo-To (JP); Jun Ogawa, Tokyo-To (JP)

Correspondence Address: Smith, Gambrell & Russell;Suite 800, 1850 M Street, N.W., Washington, DC, 20036, US

(21) Appl. No.: 10/942,103

(22) Filed: Sep. 16, 2004

(30) Foreign Application Priority Data
Sep. 17, 2003 (JP) 2003-324470

(51) Int. Cl. H01L 21/31; H01L 21/469

(52) U.S. Cl. 438/791; 438/761; 438/763

(57) ABSTRACT

The present invention is a thermal processing method of conducting a thermal process to an object to be processed, a base film having been formed on a surface of the object to be processed, the base film consisting of a SiO₂ film or a SiON film. The method includes: an arranging step of arranging the object to be processed in a processing container; and a laminating step of supplying a source gas and an ammonia gas alternatively and repeatedly, so as to form a silicon nitride film on the base film repeatedly, the source gas being selected from a group consisting of dichlorosilane, hexachlorodisilane and tetrachlorosilane.

### FIELD OF THE INVENTION

This invention relates to a thermal processing unit and a thermal processing method for conducting a predetermined process to an object to be processed, such as a semiconductor wafer, at a relatively low temperature.

Background Art

In general, in order to manufacture a desired semiconductor integrated circuit, various thermal processes including a film-forming process, an etching process, an oxidation process, a diffusion process, a modifying process or the like are carried out to a semiconductor wafer, which consists of a silicon substrate or the like. These thermal processes may be conducted by a longitudinal batch-type of thermal processing unit. In the case, at first, from a cassette that can contain a plurality of, for example 25 semiconductor wafers, semiconductor wafers are conveyed onto a longitudinal wafer boat. For example, 25 to 150 wafers (depending on the wafer size) are placed on the wafer boat in a tier-like manner. The wafer boat is conveyed (loaded) into a processing container that can be exhausted, through a lower portion thereof. After that, the inside of the processing container is maintained at an airtight state. Then, various process conditions including a flow rate of a process gas, a process pressure, a process temperature or the like are controlled to conduct a predetermined thermal process.

Herein, under the current situation wherein the semiconductor integrated circuit is requested to become more dense, more micro and thinner, for example regarding a gate insulating film used for a transistor device or a capacitor insulating film used for a capacitor or other various insulating films, making the film thinner and improving a quality of the film are desired further more. Conventionally, as an insulating film, a silicon oxide film is mainly used. However, in order to satisfy the above request, a silicon nitride film, whose leakage electric current is very small and whose dielectric constant is high, is recently paid attention to.

An example of film-forming method using a silicon nitride film is disclosed in JP Laid-Open Publication No. 2002-367990, for example. Herein, an example of conventional film-forming method of a silicon nitride film is explained. FIG. 7 is a flow chart showing an example of a film-forming process of a gate insulating film mainly having a silicon nitride film. At first, a surface of a substrate such as a silicon wafer is dry-oxidized under an atmosphere of oxygen or the like, to form a base film. At that time, the process temperature is for example 700° C., the film thickness is about 0.8 nm. In addition, the process time is for example about 4 to 6 minutes.

Next, the substrate is maintained at a high process temperature such as about 900° C., and nitrided under an ammonia-gas atmosphere, so that the surface of the substrate is modified. The process time is for example about 5 to 15 minutes. The reason of modifying the surface of the base layer by nitriding the same at a high temperature under the ammonia-gas atmosphere is to inhibit as short as possible a time for which a silicon nitride film is not deposited on the surface at the subsequent film-forming process of the silicon nitride film, that is, incubation time (deposition delay time).

Next, by using a source gas, a silicon nitride film is formed by means of a CVD (Chemical Vapor Deposition) process. At that time, dichlorosilane (hereinafter, which is also referred as DCS) is used as the source gas, and an ammonia gas is also used as a reduction gas or a nitriding gas. At that time, the process temperature is for example about 600 to 760° C. Then, deposition of the silicon nitride film is conducted under a condition wherein the incubation time is substantially zero. That is, the process is conducted with a high throughput. After that, on the insulating film formed as described above, a poly-silicon layer into which impurity such as boron (B) or the like is doped is formed as an electrode film.

In the above film-forming method of an insulating film, the incubation time can be considerably inhibited. However, boron that is impurity doped into the electrode layer may penetrate the insulating layer and diffuse in a downward direction (to the substrate).

In addition, when the surface-nitriding process as described above is conducted, an interface between the silicon wafer and the insulating layer may be nitrided. In the case, a flat band voltage may shift or mobility of carriers may be reduced.

### SUMMARY OF THE INVENTION

This invention is developed by focusing the aforementioned problems in order to resolve them effectively. The object of this invention is to provide a thermal processing method and a thermal processing unit that can form an insulating layer wherein penetration of impurity can be prevented.

This invention is a thermal processing method of conducting a thermal process to an object to be processed, a base film having been formed on a surface of the object to be processed, the base film consisting of a SiO₂ film or a SiON film, the method comprising: an arranging step of arranging the object to be processed in a processing container; and a laminating step of supplying a source gas and an ammonia gas alternatively and repeatedly into the processing container, so as to form a silicon nitride film on the base film repeatedly, the source gas being selected from a group consisting of dichlorosilane, hexachlorodisilane and tetrachlorosilane.

According to the invention, since the source gas consisting of any of dichlorosilane, hexachlorodisilane and tetrachlorosilane and the ammonia gas are alternatively and repeatedly supplied, a plurality of thin silicon nitride films are laminated. Thus, film quality of the laminated silicon nitride films is improved and penetration of impurity can be remarkably inhibited. In addition, generation of shift of a flat band voltage and/or deterioration of mobility can be also prevented.

In addition, it is preferable that in the laminating step, between a term for supplying the source gas and a term for supplying the ammonia gas, at least one of a purging step of purging the inside of the processing container by means of an inert gas and a vacuuming step of vacuuming the inside of the processing container is conducted.

In addition, it is preferable that in the laminating step, the ammonia gas is supplied into the processing container in an activated state.

The laminating step may be conducted at a relatively low temperature of 400 to 550° C. If the ammonia gas is supplied into the processing container in an activated state in the laminating step, the laminating step may be conducted at a low temperature of 300 to 400° C.

In addition, if the dichlorosilane is selected as the source gas, it is preferable that a pressure in the processing container when the dichlorosilane is supplied is within a range of 13.3 to 1333 Pa (0.1 to 10 Torr), and that a pressure in the processing container when the ammonia gas is supplied is within a range of 1013 to 13330 Pa (7.6 to 100 Torr).

In addition, after the laminating step, a CVD film-forming step of forming a silicon nitride film by means of a CVD process may be conducted. In the CVD film-forming step, a silicon series gas and an activated ammonia gas may be used.

In addition, after the laminating step, an annealing step for improving a film quality may be conducted to the silicon nitride film laminated by the laminating step.

Alternatively, after the CVD film-forming step, an annealing step for improving a film quality may be conducted to the silicon nitride film formed by the CVD film-forming step.

In addition, the method may further comprise an electrode-film forming step of forming an electrode film into which impurity is doped.

In addition, this invention is a thermal processing unit comprising: a processing container whose inside is vacuumed; an object-to-be-processed holding unit that holds an object to be processed in the processing container; a heating unit that heats the object to be processed held by the object-to-be-processed holding unit; a base-film-gas supplying unit that supplies into the processing container a gas necessary for forming a base film on a surface of the object to be processed; and a laminated-silicon-nitride-film-gas supplying unit that supplies into the processing container a gas necessary for forming a laminated silicon nitride film on a surface of the based film.

Preferably, the base film consists of a SiO₂ film or a SiON film, and the gas necessary for forming a laminated silicon film consists of a source gas and an ammonia gas, the source gas being selected from a group consisting of dichlorosilane, hexachlorodisilane and tetrachlorosilane.

The thermal processing unit may further comprise an electrode-film-gas supplying unit that supplies into the processing container a gas necessary for forming an electrode film into which impurity is doped.

In addition, the thermal processing unit may further comprise a CVD-gas supplying unit that supplies into the processing container a gas necessary for forming a silicon nitride film by means of a CVD process.

### BRIEF DESCRIPTION OF THE DRAWINGS

FIG. 1 is a schematic structural view showing an embodiment of a thermal processing unit according to the present invention;

FIG. 2 is flow charts showing a forming process of laminated thin films onto a surface of a semiconductor wafer;

FIG. 3 is diagrams, each of which shows a change of process temperature during a forming process of an insulating layer;

FIG. 4 is a flow chart showing an example of laminating step of forming laminated silicon nitride films;

FIG. 5 is a graph showing a profile of boron density in a thickness direction of a surface portion of a silicon wafer including a thin film;

FIG. 6 is a graph showing a relationship between a number of cycles in the laminating step and an incubation time when a CVD silicon nitride film is formed; and

FIG. 7 is a flow chart showing an example of film-forming process of a gate insulating film mainly consisting of a silicon nitride film.

### DESCRIPTION OF THE PREFERRED EMBODIMENT

Hereinafter, an embodiment of a thermal processing method and a thermal processing unit according to the present invention is explained with reference to attached drawings.

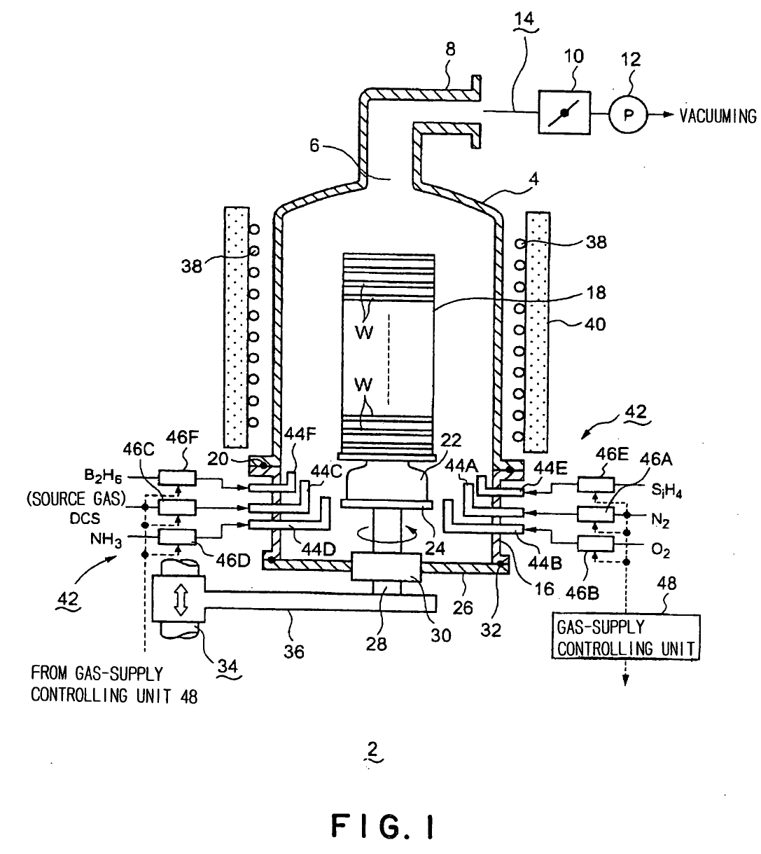

FIG. 1 is a schematic structural view showing the embodiment of a thermal processing unit according to the present invention.

As shown in FIG. 1, a thermal processing unit 2 according to the embodiment of the invention has a cylindrical processing container 4 whose lower end is open. The processing container 4 may be made of for example quartz whose heat resistance is high.

An open gas-discharging port 6 is provided at a ceiling part of the processing container 4. A gas-discharging nozzle 8 that has been bent at a right angle in a lateral direction is provided to connect with the gas-discharging port 6. A gas-discharging system 14 including a pressure-control valve 10 and a gas-discharging pump 12 and the like on the way is connected to the gas-discharging nozzle 8. Thus, the atmospheric gas in the processing container 4 can be discharged. Herein, the inside of the processing container 4 may be a vacuum or a substantially normal-pressure atmosphere, depending on a process manner.

A lower end of the processing container 4 is supported by a cylindrical manifold 16 made of for example stainless steel. Under the manifold 16, a wafer boat 18 made of quartz as an object-to-be-processed holding unit, on which a large number of semiconductor wafers W as objects to be processed are placed in a tier-like manner, is provided in a vertically movable manner. The wafer boat 18 can be inserted into and taken out from the processing container 4, through a lower opening of the manifold 16. In the embodiment, for example about 50 wafers W having 300 mm diameter may be supported in a tier-like manner at substantially the same interval (pitch) by the wafer boat 18. A sealing member 20 such as an O-ring is interposed between a lower end of the processing container 4 and an upper end of the manifold 16. Thus, airtightness between the processing container 4 and the manifold 16 is maintained.

The wafer boat 18 is placed above a table 24 via a heat-insulating cylinder 22 made of quartz. The table 24 is supported on a rotation shaft 28 that penetrates a lid member 26 for opening and closing the lower end opening of the manifold 16.

For example, a magnetic-fluid seal 30 is provided at a penetration part of the lid member 26 by the rotation shaft 28. Thus, the rotation shaft 28 can rotate while maintaining airtightness by the lid member 26. In addition, a sealing member 32 such as an O-ring is provided between a peripheral portion of the lid member 26 and a lower end portion of the manifold 16. Thus, airtightness between the lid member 26 and the manifold 16 is maintained, so that airtightness in the processing container 4 is maintained.

The rotation shaft 28 is attached to a tip end of an arm 36 supported by an elevating mechanism 34 such as a boat elevator. When the elevating mechanism 34 is moved up and down, the wafer boat 18 and the lid member 26 and the like may be integrally moved up and down.

Herein, the table 24 may be fixed on the lid member 26. In the case, the wafer boat 18 doesn't rotate while the process to the wafers W is conducted.

A heating unit 38, which consists of for example a heater made of a carbon-wire disclosed in JP Laid-Open Publication No. 2003-209063, is provided at a side portion of the processing container 4 so as to surround the processing container 4. The heating unit 38 is capable of heating the semiconductor wafers W located in the processing container 4. The carbon-wire heater can achieve a clean process, and is superior in characteristics of rise and fall of temperature. Thus, the carbon-wire heater is suitable for a plurality of consecutive processes like the present invention.

A heat insulating material 40 is provided around the outside periphery of the heating unit 38. Thus, the thermal stability of the heating unit 38 is assured.

In addition, a gas-introducing unit 42 is provided at the manifold 16, in order to introduce various kinds of gases into the processing container 4. Specifically, as the gas-introducing unit 42, six gas nozzles 44A, 44B, 44C, 44D, 44E and 44F are provided, each of which penetrates the side wall of the manifold 16. Herein, as an example, a nitrogen gas (N₂) is adapted to be introduced from the gas nozzle 44A, an oxygen gas (O₂) is adapted to be introduced from the gas nozzle 44B, a source gas such as a DCS gas is adapted to be introduced from the gas nozzle 44C, an ammonia gas (NH₃) is adapted to be introduced from the gas nozzle 44D, a silane gas (SiH₄) is adapted to be introduced from the gas nozzle 44E, and a B₂H₆ gas is adapted to be introduced as a dope gas from the gas nozzle 44F, if necessary respectively, in such a manner that the respective flow rates can be controlled. Specifically, gas control units 46A to 46F including mass flow controllers and/or open-close valves are respectively connected to the gas nozzles 44A to 44F. Then, according to an instruction from a gas-supply controlling unit 48 consisting of a micro computer or the like, supply start, supply flow rate and supply stop of each gas can be controlled independently.

Next, a thermal processing method carried out by using the thermal processing unit 2 is explained.

When the semiconductor wafers W consisting of for example silicon wafers are unloaded and the thermal processing unit is under a waiting state, the processing container 4 is maintained at a temperature, which is lower than a process temperature. Then, the wafer boat 18 on which a large number of, for example fifty, wafers W at a normal temperature are placed is moved up and loaded into the processing container 4 from the lower portion thereof. The lid member 26 closes the lower end opening of the manifold 16, so that the inside of the processing container 4 is hermetically sealed.

Then, the inside of the processing container 4 is vacuumed and maintained at a predetermined process pressure. On the other hand, electric power supplied to the heating unit 38 is increased so that the wafer temperature is raised and stabilized at a process temperature for the thermal process. After that, predetermined process gases are supplied from the gas nozzles 44A to 44F of the gas introducing unit 42 into the processing container 4 while the flow rates of the process gases are controlled.

Each process gas ascends in the processing container 4 and comes in contact with the wafers W contained in the rotating wafer boat 18. Thus, the thermal process is conducted to the wafer surfaces. Then, the respective process gases and a reaction product gas are discharged outside from the gas-discharging port 6 at the ceiling part of the processing container 4.

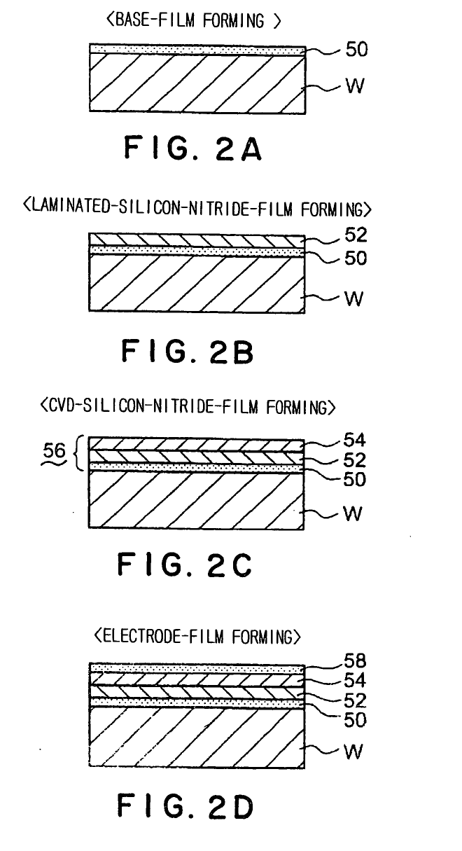

Next, as an example of thermal process conducted to the semiconductor wafers W, a forming process of a thin film is explained. FIGS. 2A to 2D are flow charts showing a process of forming thin films onto a surface of a semiconductor wafer. Herein, a gate insulating layer is formed.

At first, on a surface of a semiconductor wafer W consisting of for example a silicon wafer, a base film 50 consisting of a SiO₂ film or a SiON film is formed (see FIG. 2A). Then, on the base film 50, according to the characteristic laminating step of the present invention, that is, according to an absorption reaction instead of a gas phase reaction, a laminated silicon nitride film 52 consisting of a plurality of laminated thin silicon nitride films is formed (see FIG. 2B). In the laminating step, as described below, the source gas and the ammonia gas are alternatively and repeatedly supplied under a relatively low process temperature such as 400 to 550° C.

Next, on the laminated silicon nitride film 52 formed as described above, a CVD silicon nitride film 54 is formed by means of a CVD (Chemical Vapor Deposition) process (CVD film-forming step: see FIG. 2C). The process temperature in the CVD film-forming step is higher than that in the previous laminating step and is a relatively high temperature such as about 600 to 760° C. Thus, the gate insulating layer 56 consisting of a film-laminated structure of the base film 50, the laminated silicon nitride film 52 and the CVD silicon nitride film 54 is formed.

After the gate insulating layer 56 is formed, an electrode-film forming step is conducted so that a poly-silicon film is deposited on the gate insulating layer 56 to form an electrode film 58, wherein for example boron is doped into the poly-silicon film as impurity (see FIG. 2D). At that time, as the source gas, for example SiH₄ and B₂H₆ and the like can be used. In addition, the process temperature is within a range of about 500 to 700° C. The impurity is not limited to the boron. For example, depending on device design, various impurity, for example phosphorus and arsenic and the like, can be used.

In addition, the base-film forming step shown in FIG. 2A, the laminating step for forming the laminated silicon nitride film shown in FIG. 2B, the CVD-silicon-nitride-film forming step shown in FIG. 2C, and the electrode forming step shown in FIG. 2D are serially conducted in the single thermal processing unit shown in FIG. 1. Herein, the electrode forming step may be conducted at another thermal processing unit.

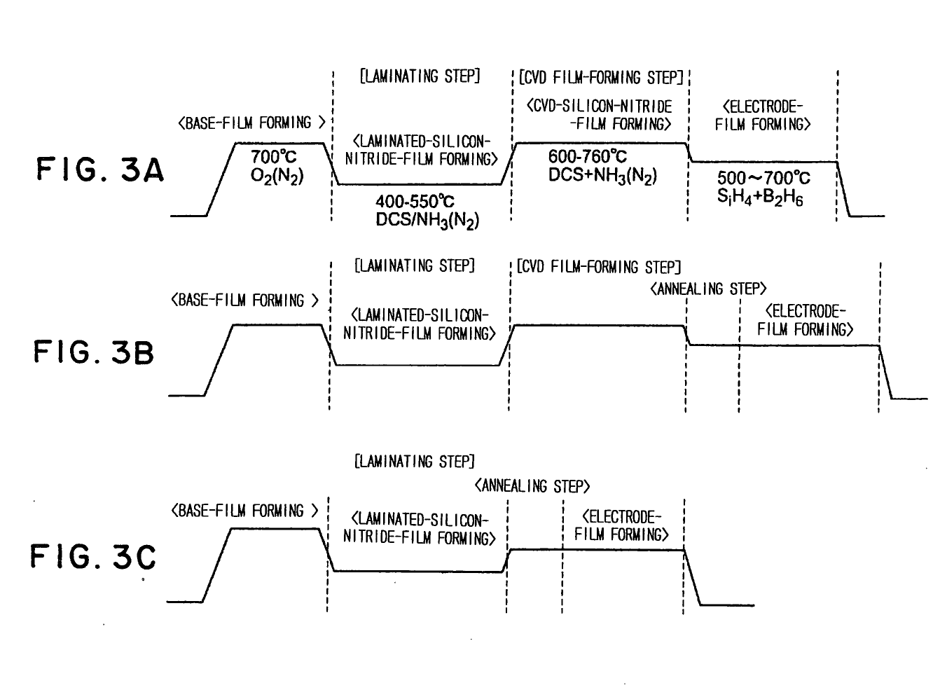

Herein, the flow of the base-film forming step (FIG. 2A) to the CVD-silicon-nitride-film forming step (FIG. 2C) is explained with reference to FIGS. 3A to 3C. FIGS. 3A to 3C are diagrams, each of which shows a change of process temperature during a forming process of an insulating layer.

As shown in FIG. 3A, in the base-film forming step, the process temperature is set to about 700° C., for example an O₂ gas is supplied as a process gas, and an N₂ gas is also supplied if necessary. Thus, a dry-oxidation process is conducted. Alternatively, a wet-oxidation process is conducted by generating vapor from an H₂ gas and an O₂ gas. Then, a base film 50 consisting of a SiO₂ film is formed on a surface of the silicon wafer W, or a base film 50 consisting of a SiON film is formed thereon by adding NH₃, NO, N₂O or the like (see FIG. 2A). The thickness of the base film 50 is about 0.8 nm. In FIG. 1, gas nozzles for H₂, NO and N₂O are omitted.

Next, in order to form the laminated silicon nitride film, a temperature of the wafer is decreased, and the process temperature is maintained at about 400 to 550° C. The process temperature is a temperature at which a vapor phase reaction is not caused but an absorption reaction is caused. Under the condition, as described below, the DCS gas as a source gas and the NH₃ gas are alternatively and intermittently supplied to form a plurality of thin silicon nitride films in a laminated manner. Thus, the laminated silicon nitride film 52 is formed (see FIG. 2B). At that time, if necessary, the N₂ gas may be also supplied. Herein, if the process temperature is higher than 550° C., the condition may be within a CVD region. To the contrary, if the process temperature is lower than 400° C., the film itself may not be formed. Herein, the thickness of the laminated silicon nitride film 52 is for example about 0.1 to 0.3 nm.

Next, in order to form the CVD silicon nitride film, the temperature of the wafer is increased again, and the process temperature is maintained at about 600 to 760° C. The process temperature is a temperature at which a CVD reaction is caused. Under the condition, the DCS gas as a source gas and the NH₃ gas are supplied at the same time so as to form the CVD silicon nitride film 54 by a CVD reaction (see FIG. 2C). In the case, if necessary, the N₂ gas may be supplied. The thickness of the CVD silicon nitride film 54 is for example about 0.8 to 1.0 nm. Through the above steps, the gate insulating layer 56 is completed.

Next, in order to form the electrode film, while the temperature of the wafer is maintained within a range of about 500 to 700° C., the SiH₄ gas and the B₂H₆ gas are supplied into the processing container 4 at the same time, so that a poly-silicon film into which boron is doped is formed as the electrode film (see FIG. 2D). Herein, if the wafer temperature at the CVD-film-forming step and the wafer temperature at the electrode-film-forming step are set to the same, a time necessary for rise and fall of the wafer temperature can be omitted.

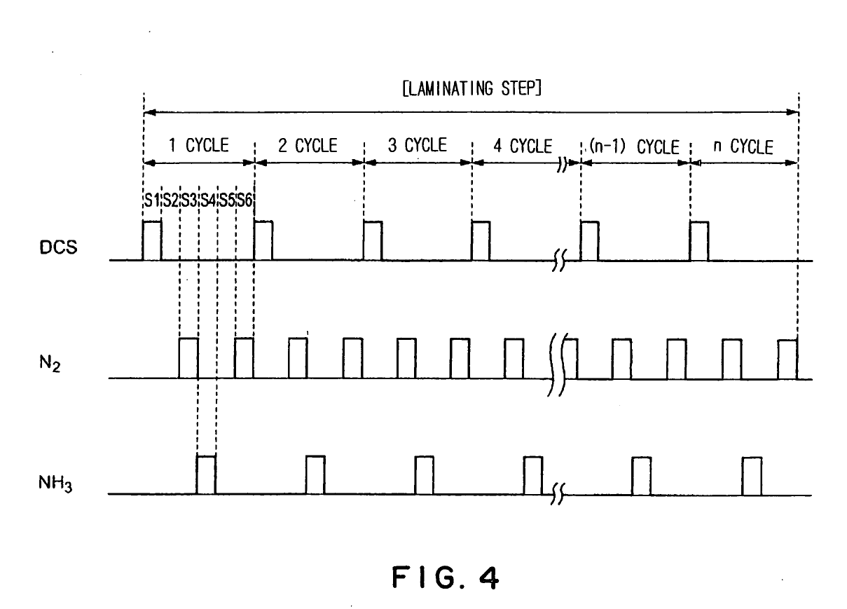

Next, the laminating step of forming the laminated silicon nitride film is explained in more detail, which is the feature of the present invention. FIG. 4 shows an example of laminating step of forming a laminated silicon nitride film.

As shown in FIG. 4, in the case, a DCS gas is used as a source gas, an NH₃ gas is used as a nitriding gas, and an N₂ gas is used as a purge gas. Herein, one cycle consists of six steps S1 to S6. In addition, the inside of the processing container 4 is continuously vacuumed during the process.

At first, when the temperature of the wafer W is stabilized at a process temperature that is a predetermined temperature within a range of 400 to 550° C., for example 500° C., the DCS gas is supplied at a flow rate of for example about 1000 sccm in a step S1. The term of the step S1 is for example about 7 minutes. Thus, if the condition is adjusted for the whole surface of the base film 50, the DCS gas adheres or absorbs on the surface by each molecular.

Then, in a step S2, supply of all the gases is stopped, but the vacuuming is continued. Thus, the DCS gas remaining in the processing container 4 is discharged so that the pressure in the processing container 4 is decreased to a base pressure. The term of the step S2 is for example about 4 minutes.

Then, in a step S3, the N₂ gas is supplied to conduct a purge step, so that the DCS gas remaining in the processing container 4 is completely discharged. At that time, the flow rate of the N₂ gas is for example about 1000 sccm. The term of the step S3 is for example about 1 minute.

Then, in a step S4, the NH₃ gas is supplied. The NH₃ gas reacts with DSC-gas molecules adhering on the wafer surface so that a thin silicon nitride film (SiN) for example having a thickness corresponding to one molecule is formed. At that time, if necessary, the N₂ gas may be supplied. At that time, the flow rate of the NH₃ gas is for example about 1000 sccm. The term of the step S4 is for example about 4.5 minutes. In addition, in this step, the DCS gas is supplied into the processing container 4 prior to the NH₃ gas because this can shorten the incubation time further more.

Then, in a step S5, supply of all the gases is stopped, but the vacuuming is continued. Thus, the NH₃ gas remaining in the processing container 4 is discharged so that the pressure in the processing container 4 is decreased to the base pressure. The term of the step S5 is for example about 4 minutes.

Then, in a step S6, the N₂ gas is supplied to conduct a purge step, so that the NH₃ gas remaining in the processing container 4 is completely discharged. At that time, the flow rate of the N₂ gas is for example about 10000 sccm. The term of the step S6 is for example about 1 minute.

Through the above steps, one cycle of thin-film forming process is completed. After that, the cycle consisting of the steps S1 to S6 is repeated plural times. Thus, a plurality of the silicon nitride films, each of which has a thickness of one molecule level, is formed and laminated.

FIG. 4 shows a case wherein n (a positive integer) cycles are repeated. The value of n is preferably for example about 5 to 30. In the case shown in FIG. 4, the process pressure of a step for supplying the DCS gas is within a range of 13.3 to 1333 Pa (0.1 to 10 Torr), and the process pressure of a step for supplying the NH₃ gas is within a range of 1013 to 13330 Pa (7.6 to 100 Torr).

The term of one supplying step of the DCS gas or the NH₃ gas is preferably about 1 to 20 minutes in view of improvement of the throughput, although it also depends on thickness to be formed. Even if the term is longer than 20 minutes, the film thickness is saturated, i.e. is not increased more.

In addition, in the case shown in the drawing, between the supplying step of the source gas (DCS gas) and the supplying step of the NH₃ gas, both steps of a vacuuming step of conducting a vacuuming operation while supply of all the gases is stopped and a purging step of conducting a vacuuming operation while the N₂ gas is supplied are conducted. However, this invention is not limited thereto. Only one step of the vacuuming step and the purging step may be conducted.

Through the above method, the laminated silicon nitride film 52 whose film quality is good can be formed. In addition, the incubation time in forming the CVD silicon nitride film 54 can be remarkably inhibited.

Furthermore, since the laminated silicon nitride film is formed at the relatively low temperature of 400 to 550° C., which is lower than prior art, the nitrogen doesn't diffuse toward an interface to the silicon wafer surface so much, that is, the interface is difficult to be nitrided. Thus, mobility of carriers can be maintained high, and shift of a flat band voltage can be inhibited.

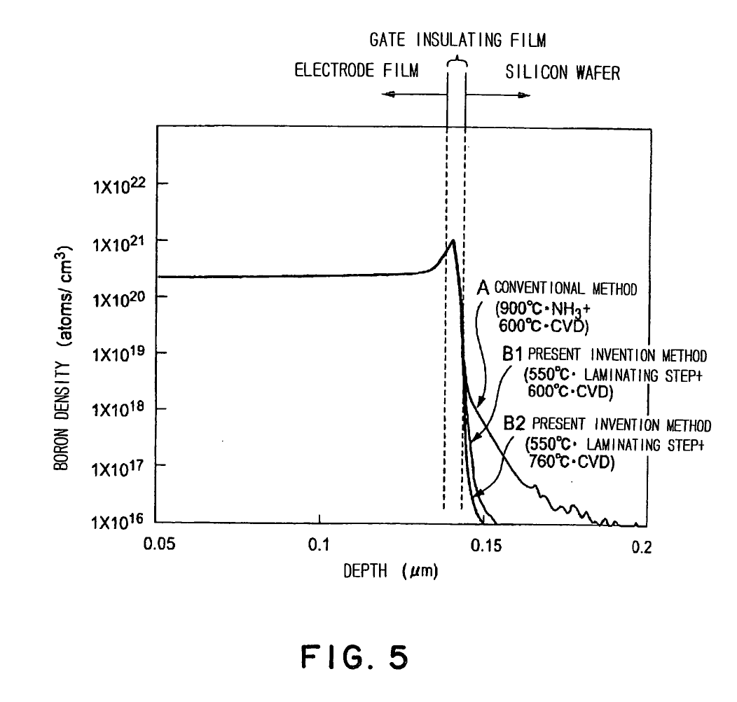

Herein, resistance of a gate insulating layer against penetration of boron was evaluated. With reference to FIG. 5, the evaluation result is explained. FIG. 5 is a graph showing a profile of boron density in a thickness direction of a surface portion of a silicon wafer including a thin film. In the drawing, a curve A shows a profile of boron density in a gate insulating layer formed according to a conventional method, and curves B1, B2 respectively show profiles of boron density in gate insulating layers formed according to the present invention method.

In the conventional method shown by the curve A, a surface nitridation process was conducted at 900° C. in the presence of NH₃, and then a silicon nitride film was deposited at 600° C. by means of a CVD process so that a gate insulating layer was formed (see FIG. 7). On the other hand, in the present invention method shown by the curve B1, the laminating step was conducted at 550° C., and then a silicon nitride film was deposited at 600° C. by means of a CVD process so that a gate insulating layer was formed. In the present invention method shown by the curve B2, the laminating step was conducted at 550° C., and then a silicon nitride film was deposited at 760° C. by means of a CVD process so that a gate insulating layer was formed.

As clearly seen from FIG. 5, in the conventional method shown by the curve A, the boron, which is impurity in the electrode film, diffuses to a deep portion of the silicon wafer, specifically to a depth of about 0.2 μm, which is not preferable.

To the contrary, in the present invention method shown by the curves B1, B2, the boron diffuses only to a depth of about 0.15 μm. That is, penetration of the impurity can be remarkably inhibited.

Next, a relationship between a number of cycles (a number of repetitions) in forming the laminated silicon nitride film and an incubation time was studied. The evaluation result is explained.

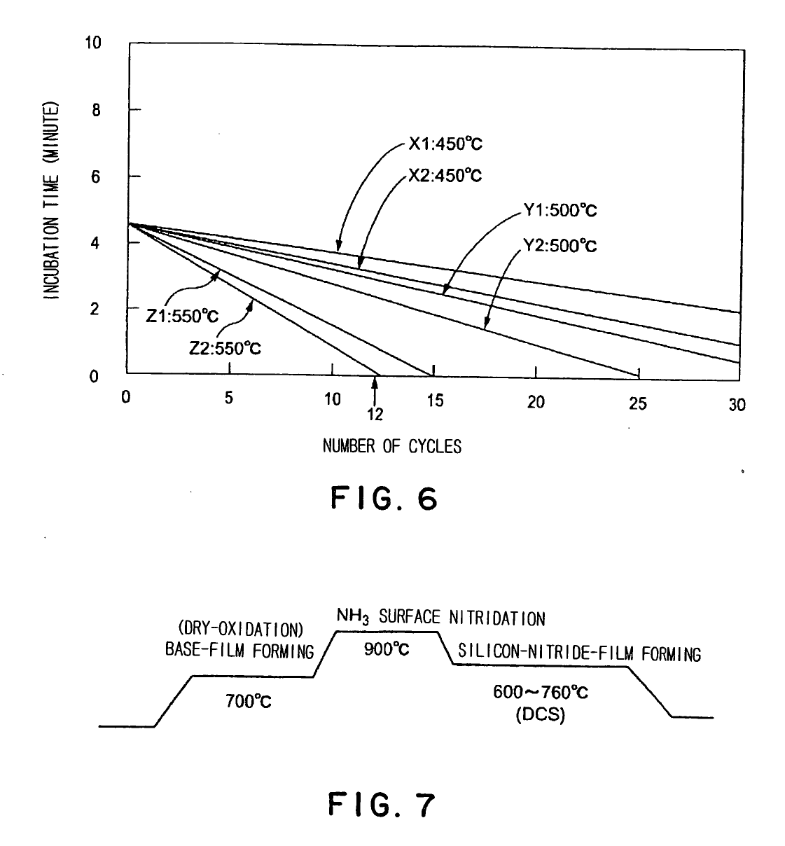

FIG. 6 is a graph showing a relationship between a number of cycles in the laminating step and an incubation time in forming a CVD silicon nitride film. In the drawing, characteristic lines X1, X2 correspond to a process temperature of 450° C. in the laminating step, characteristic lines Y1, Y2 correspond to a process temperature of 500° C. in the laminating step, and characteristic lines Z1, Z2 correspond to a process temperature of 550° C. in the laminating step. In addition, the characteristic lines X1, Y1, Z1 correspond to a process pressure of 7.6 Torr at supplying the NH₃ gas in the laminating step, and the characteristic lines X2, Y2, Z2 correspond to a process pressure of 38 Torr at supplying the NH₃ gas in the laminating step.

As clearly seen from FIG. 6, if the process temperature is higher in the laminating step within a temperature range wherein a CVD film-forming is not caused, the incubation time is shorter. In addition, if the process pressure is higher when the NH₃ gas is supplied, the incubation time may be inhibited to be shorter. In particular, as shown by the characteristic line Z2, if the process temperature is set to 550° C. and the process pressure at supplying the NH₃ gas is set to 38 Torr, it was confirmed that the incubation time can be inhibited to be substantially zero by setting the number of cycles in the laminating step to “12”.

In the above embodiment, as shown in FIG. 3A, after the CVD silicon nitride film is formed at the CVD film-forming step, the process is completed. However, this invention is not limited thereto. As shown in FIG. 3B, an annealing step may be conducted after the CVD film-forming step and just before the electrode forming step, so that the CVD silicon nitride film may be subjected to the annealing process to improve a film quality thereof. The process temperature at the annealing step is lower than that at the CVD film-forming step, and is for example about 700° C. In addition, as an atmospheric gas at the annealing step, an O₂ gas, an N₂ gas, an N₂O gas, and the like can be used.

In addition, as shown in FIG. 3C, after the laminated silicon nitride film is formed at the laminating step, the CVD film-forming step explained with reference to FIG. 3A may not be conducted, but an annealing process may be directly conducted, so that the laminated silicon nitride film may be subjected to the annealing process to improve a film quality thereof. In this case, after that, an electrode forming step is conducted. The process temperature at the annealing step is for example about 700° C. In addition, as an atmospheric gas, an O₂ gas, an N₂ gas, an N₂O gas, and the like can be used.

In the above respective embodiments, the DCS gas is used as a source gas. However, instead of this, another silicon series gas such as hexachlorodisilane (HCD) or tetrachlorosilane (TCS) may be used.

In addition, in forming the CVD silicon nitride film, instead of the above silicon series gases, other silicon series gases including silane, hexamethyldisilazane (HMDS), disilylamine (DSA), trisilylamine (TSA), bis(tert-butyl aminosilane) (BTBAS) can be also used.

In addition, in the above embodiment, the NH₃ gas is supplied in the laminating step for the silicon nitride film and in the CVD-silicon-nitride-film forming step. Herein, the NH₃ gas may be supplied into the processing container 4 in an activated state. If the NH₃ gas is activated and supplied, the process temperature can be decreased to about 300 to 400° C.

The NH₃ gas may be activated by means of plasma, as disclosed in JP laid-Open Publication No. 5-251391 and JP laid-Open Publication No. 2002-280378, for example. The activated NH₃ gas is introduced into the processing container, in which the wafer W is arranged.

In addition, in the above explanation, the gate insulating layer is formed. However, this invention is also applicable to a case wherein another insulating layer such as a capacitor insulating layer is formed.

1. A thermal processing method of conducting a thermal process to an object to be processed, a base film having been formed on a surface of the object to be processed, the base film consisting of a SiO₂ film or a SiON film, the method comprising:
an arranging step of arranging the object to be processed in a processing container; and
a laminating step of supplying a source gas and an ammonia gas alternatively and repeatedly into the processing container, so as to form a silicon nitride film on the base film repeatedly, the source gas being selected from a group consisting of dichlorosilane, hexachlorodisilane and tetrachlorosilane.

2. A thermal processing method according to claim 1, wherein
in the laminating step, between a term for supplying the source gas and a term for supplying the ammonia gas, at least one of a purging step of purging the inside of the processing container by means of an inert gas and a vacuuming step of vacuuming the inside of the processing container is conducted.

3. A thermal processing method according to claim 1, wherein
in the laminating step, the ammonia gas is supplied into the processing container in an activated state.

4. A thermal processing method according to claim 1, wherein
the laminating step is conducted at a relatively low temperature of 400 to 550° C.

5. A thermal processing method according to claim 3, wherein
the laminating step is conducted at a low temperature of 300 to 400° C.

6. A thermal processing method according to claim 1, wherein
the dichlorosilane is selected as the source gas,
a pressure in the processing container when the dichlorosilane is supplied is within a range of 13.3 to 1333 Pa (0.1 to 10 Torr), and
a pressure in the processing container when the ammonia gas is supplied is within a range of 1013 to 13330 Pa (7.6 to 100 Torr).

7. A thermal processing method according to claim 1, wherein
after the laminating step, a CVD film-forming step of forming a silicon nitride film by means of a CVD process is conducted.

8. A thermal processing method according to claim 7, wherein
in the CVD film-forming step, a silicon series gas and an activated ammonia gas are used.

9. A thermal processing method according to claim 1, wherein
after the laminating step, an annealing step for improving a film quality is conducted to the silicon nitride film laminated by the laminating step.

10. A thermal processing method according to claim 7, wherein
after the CVD film-forming step, an annealing step for improving a film quality is conducted to the silicon nitride film formed by the CVD film-forming step.

11. A thermal processing method according to claim 1, further comprising
an electrode-film forming step of forming an electrode film into which impurity is doped.

12. A thermal processing unit comprising:
a processing container whose inside is vacuumed,
an object-to-be-processed holding unit that holds an object to be processed in the processing container,
a heating unit that heats the object to be processed held by the object-to-be-processed holding unit,
a base-film-gas supplying unit that supplies into the processing container a gas necessary for forming a base film on a surface of the object to be processed, and
a laminated-silicon-nitride-film-gas supplying unit that supplies into the processing container a gas necessary for forming a laminated silicon nitride film on a surface of the based film.

13. A thermal processing unit according to claim 12, wherein
the base film consists of a SiO₂ film or a SiON film.

14. A thermal processing unit according to claim 12, wherein
the gas necessary for forming a laminated silicon nitride film consists of a source gas and an ammonia gas, the source gas being selected from a group consisting of dichlorosilane, hexachlorodisilane and tetrachlorosilane.

15. A thermal processing unit according to claim 12, further comprising
an electrode-film-gas supplying unit that supplies into the processing container a gas necessary for forming an electrode film into which impurity is doped.

16. A thermal processing unit according to claim 12, further comprising
a CVD-gas supplying unit that supplies into the processing container a gas necessary for forming a silicon nitride film by means of a CVD process.
